(19) United States
(12) Patent Application Publication
(10) Pub. No.: US 2025/0185389 A1
(43) Pub. Date: Jun. 5, 2025

(54) IMAGE SENSOR WITH METAL-INSULATOR-METAL STORAGE ELEMENTS

(71) Applicant: TAIWAN SEMICONDUCTOR MANUFACTURING COMPANY, LTD., Hsinchu (TW)

(72) Inventors: Chun-Liang Lu, Tainan (TW); Chia-Yu Wei, Tainan (TW); Chun-Hao Chou, Tainan (TW); Kuo-Cheng Lee, Tainan (TW)

(21) Appl. No.: 18/527,532

(22) Filed: Dec. 4, 2023

(51) Int. Cl. H01L 27/146; H01L 27/148

(52) U.S. Cl. CPC H10F 39/026; H10F 39/018; H10F 39/80; H10F 39/8053; H10F 39/809

(57) ABSTRACT

In a method of fabricating an image sensor, a photosensor wafer is formed, comprising an array of photosensors. A signal processing wafer is formed, comprising signal processing circuitry configured to receive and process photocharge collected by the photosensors of the photosensor wafer. A storage wafer is formed, comprising metal-insulator-metal (MIM) storage elements. The photosensor wafer is secured to a first side of the storage wafer, thereby electrically connecting the photosensors of the photosensor wafer and MIM storage elements of the storage wafer. The signal processing wafer is secured to a second side of the storage wafer, thereby electrically connecting the MIM storage elements of the storage wafer with the signal processing circuitry of the signal processing wafer.

### BACKGROUND

The following relates to the image sensor arts, event vision sensor (EVS) arts, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates an electrical schematic of an image sensor with event vision sensor (EVS) photosensors, which includes a photosensor layer, a storage layer, and a signal processing layer.

FIG. 2 diagrammatically illustrates a side sectional view of an image sensor with EVS photosensors, in which a photosensor layer is disposed on and/or in a photosensor wafer, a storage layer is disposed on and/or in a storage wafer, and a signal processing layer is disposed on and/or in a signal processing wafer.

FIG. 3 diagrammatically illustrates an isolation side sectional view of the storage wafer of the image sensor of FIG. 2.

FIG. 4 illustrates a flowchart of a fabrication method for fabricating the image sensor of FIG. 2.

FIG. 5 illustrates plan view of some suitable photosensor arrangements for an image sensor that includes a color image sensor with red, green, blue photosensors and an EVS with EVS photosensors.

FIG. 6 diagrammatically illustrates side sectional views of some suitable metal-insulator-metal (MIM) storage elements for use in increasing photocharge storage capacity of photosensors of an image sensor.

FIG. 7 diagrammatically illustrates some suitable sharing of MIM storage elements by multiple photosensors of an image sensor.

FIG. 8 diagrammatically illustrates side sectional views of some suitable MIM storage elements for use in increasing photocharge storage capacity of photosensors of an image sensor.

FIG. 9 diagrammatically illustrates top views of some suitable MIM storage elements for use in increasing photocharge storage capacity of photosensors of an image sensor.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Image sensors are desirably compact with high dynamic range, and for many applications are desirably color image sensors. These goals of a compact color image sensor with high dynamic range can, however, be difficult to achieve in a single image sensor. Miniaturizing an image sensor provides a smaller area for each photosensor, and color image sensors with red, green, and blue photosensors further crowd the photosensors together and reduce the available area for each photosensor. However, a smaller photosensors area reduces the per-photosensor area for photocharge storage. (The photocharge is the electrical charge accumulated due to light interaction with the photodiode or other photodetector of the photosensor). The photocharge storage capacity of a photosensor may, for example, be quantified by a full well capacity (FWC). Reduction in the per-photosensor area for photocharge storage (and hence the FWC) in turn reduces the dynamic range of the photosensor.

Some image sensors also desirably have high sensitivity to motion. Motion sensitivity can be achieved by a fast shutter speed, either using a physical shutter or an electronic shutter. However, this approach may not be sufficient to achieve sensitivity to high-speed motion without blurring. To address this problem, the image sensor may have dedicated event vision sensor (EVS) photosensors that include comparator circuitry to detect events as changes in detected light intensity that exceed a threshold. Including EVS photosensors in a color image sensor entails further miniaturization of the photosensors. Moreover, a higher photocharge storage capacity may be employed for the EVS photosensors.

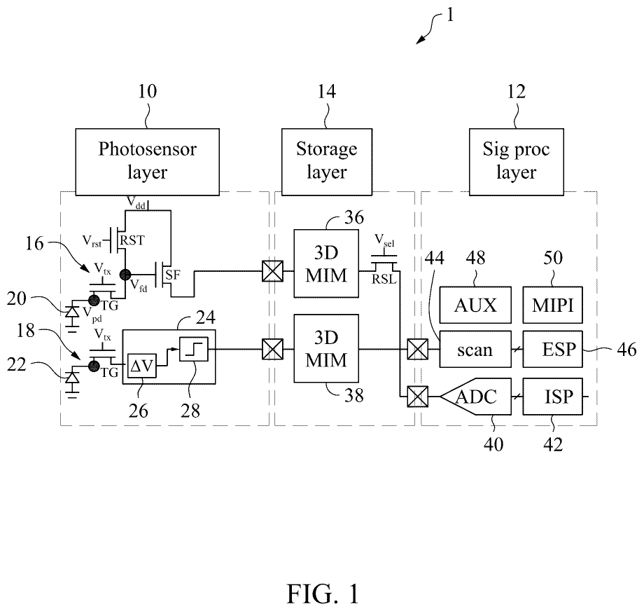

With reference to FIG. 1, in embodiments disclosed herein these problems are remediated by providing an image sensor 1 that includes a photosensor layer 10, a signal processing layer 12, and a storage layer 14 that is interposed between the photosensor layer 10 and the signal processing layer 12. The photosensor layer 10 comprises an array of photosensors, which in the illustrative embodiment of FIG. 1 include an illustrative conventional photosensor 16 (e.g., a red, green, or blue photosensor of an RGB pixel of a color image sensor) and an illustrative EVS photosensor 18 which is part of an EVS. It will be appreciated that a typical image sensor will include a two-dimensional (2D) array of conventional photosensors 16 and/or a 3D array of EVS photosensors 18, of which one representative conventional photosensor 16 and one representative EVS photosensor 18 are shown in FIG. 1. In some embodiments, the image sensor may include only conventional photosensors 16 (e.g., including conventional photosensors with red, green, and blue filters to provide a color image sensor). In some embodiments, the image sensor may include only EVS photosensors 18. In some embodiments (as shown in FIG. 1), the image sensor may include both conventional photosensors 16 (e.g., including conventional photosensors with red, green, and blue filters to provide a color image sensor) and EVS photosensors 18.

The signal processing layer 12 includes signal processing circuitry configured to receive and process photocharge collected by the photosensors 16, 18 of the photosensor layer 10. The specific signal processing circuitry included in the signal processing layer 12 depends on the type of image sensor 1 (e.g., color image sensor, monochrome image sensor, EVS image sensor, or a combination of a color or monochrome image sensor and an EVS image sensor) and optionally on other desired features of the image sensor such as optional image processing functionality, optional image transmission capabilities (e.g., wireless image data transmission, wired image data transmission, et cetera).

The illustrative photosensor 16 includes a photodiode 20 or other photosensitive device outputting a light-dependent voltage V_{pd}, and biasing circuitry including transfer gate TG, source follower SF, and reset RST transistor circuitry, and is powered by a voltage power supply (V_{dd}). This is merely one nonlimiting illustrative photosensor topology, and other photosensor topologies including the photodiode 20 or other photosensitive device can be employed as the photosensor 16.

The illustrative EVS photosensor 18 includes a photodiode 22 or other photosensitive device and biasing circuitry including transfer gate TG, and further includes EVS circuitry 24 for generating events in response to light intensity changes of a predesigned magnitude. The illustrative EVS circuitry 24 includes a delta modulator 26 that determines a voltage difference between a reference voltage Vᵣ previously output by the photodiode 22 at a prior time to and the current output voltage V output by the photodiode 22 at a present time t. Hence, the output of the delta modulator 26 is suitably proportional to V−Vᵣ. The voltage difference is thresholded by a comparator 28 to determine whether an EVS event has occurred. In some embodiments, the EVS event could be either a positive event (light intensity increasing at a magnitude greater than a positive change threshold) or a negative even (light intensity decreasing at a magnitude greater than a negative change threshold). This is merely one nonlimiting illustrative EVS photosensor topology, and other photosensor topologies including the photodiode 22 or other photosensitive device can be employed as the EVS photosensor 18.

The storage layer 14 includes metal-insulator-metal (MIM) storage elements 36 electrically connected in series between the photosensors 16 of the photosensor layer 10 and signal processing circuitry of the signal processing layer 12; and/or includes MIM storage elements 38 electrically connected in series between the EVS photosensors 18 of the photosensor layer 10 and signal processing circuitry of the signal processing layer 12. The storage layer 14 may optionally include additional circuitry besides the MIM storage elements 36 and/or 38, such as an illustrative row selector transistor RSL for selecting a row of the conventional photosensor array (comprising the photosensors 16) for signal processing based on a voltage Vₛₑₗ applied to the base of the row selector transistor RSL. Various embodiments of the MIM storage elements 36 and/or 38 will be described later herein. The storage elements 36 and/or 38 provide increased photocharge storage capacity for the respective photosensors 16 and/or 18, since additional photocharge can be stored in the storage elements 36 and/or 38. (The photocharge is the electrical charge accumulated due to light interaction with the photodetector 20 or 22). In this way, the dynamic range of the photosensors (which is dependent on the photocharge storage capacity, e.g., as quantified by FWC or another suitable metric) is advantageously increased.

The signal processing layer 12 of the nonlimiting illustrative embodiment of FIG. 1 includes: circuitry 40, 42 for processing photocharge collected by the photosensors 16 (including such collected photocharge that is stored in the series-connected storage elements 36) to generate an image or imaging data; circuitry 44, 46 for processing photocharge collected by the EVS photosensors 18 (including such collected photocharge that is stored in the series-connected storage elements 38) to generate an EVS image or EVS imaging data; and optional additional circuitry 48, 50 for providing other functionality.

For processing photocharge collected by the photosensors 16 (including such collected photocharge that is stored in the series-connected storage elements 36), the illustrative signal processing layer 12 of FIG. 1 includes an analog-to-digital converter (ADC) 40 that digitizes photocharge accumulated by the photosensor 16 (including such collected photocharge that is stored in the series-connected storage element 36) and optional image signal processing (ISP) circuitry 42 for further processing the digitized imaging data. The signal processing circuitry 40, 42 for processing imaging data collected by the photosensors 16 may operate in conjunction with the row selector circuitry RSL of the storage layer 14. For example, there may be N ADC/ISP signal processing chains 40, 42 where N is the number of columns of photosensors 16 in the photosensor array, and the row selector circuit RSL sequentially cycles through M rows of photosensors 16 in the photosensor array to acquire an M×N pixel array of imaging data. The ISP circuitry 42 may perform other signal processing functionality such as organizing the pixel values (which scale with the photocharge accumulated by corresponding photosensors 16) into red, green, and blue images (in the case of a color sensor array), converting red, green, and blue pixel values into an RGB pixel value, organizing pixel values into successive image frames, and/or so forth. The illustrative signal processing circuitry 40, 42 is a nonlimiting illustrative example, and more generally other signal processing topologies are contemplated.

In the case of the EVS photosensors 18, the circuitry 44, 46 processes photocharge collected by the EVS photosensors 18 after the photocharge is initially processed by the EVS circuitry 24. The illustrative EVS signal processing circuitry 44, 46 includes a scan sub-circuit 44 that scans over the EVS photosensors 18 of the sensor array, and event signal processing (ESP) circuitry 46 that processes the event data to generate an event image or imaging data. The illustrative EVS signal processing circuitry 44, 46 is a nonlimiting illustrative example, and more generally other EVS signal processing topologies are contemplated.

The additional circuitry 48, 50 of the illustrative signal processing layer 12 includes auxiliary circuitry 48 which may perform various types of additional digital image processing, and mobile industry processor interface (MIPI) circuitry 50 providing the physical (PHY) layer of a digital camera, digital camera-equipped cellular telephone (cellphone), or other digital camera-equipped mobile device. Again, this is a nonlimiting illustrative example, and more generally other and/or additional circuitry may be included for providing various additional functionality for the image sensor 1.

An image sensor 1 of FIG. 1 is presented by way of an electrical schematic including the illustrative photosensor layer 10, a storage layer 14, and signal processing layer 12. These circuitry layers may be variously fabricated. In one physical implementation, the three layers 10, 12, and 14 are all fabricated on a single silicon wafer (or diced die). In another physical implementation, the image sensor 1 is fabricated on two silicon wafers (or diced dies) that are bonded together with electrical interconnects between the wafers (or dies), with the photosensor and storage layers 10 and 14 fabricated on one silicon wafer (or diced die) and the signal processing layer 12 fabricated on the other silicon wafer (or diced die). In yet another physical implementation, the image sensor 1 is fabricated on two silicon wafers (or diced dies) that are bonded together with electrical interconnects between the wafers (or dies), with the photosensor layer 10 fabricated on one silicon wafer (or diced die) and the storage and signal processing layers 12 and 14 fabricated on the other silicon wafer (or diced die).

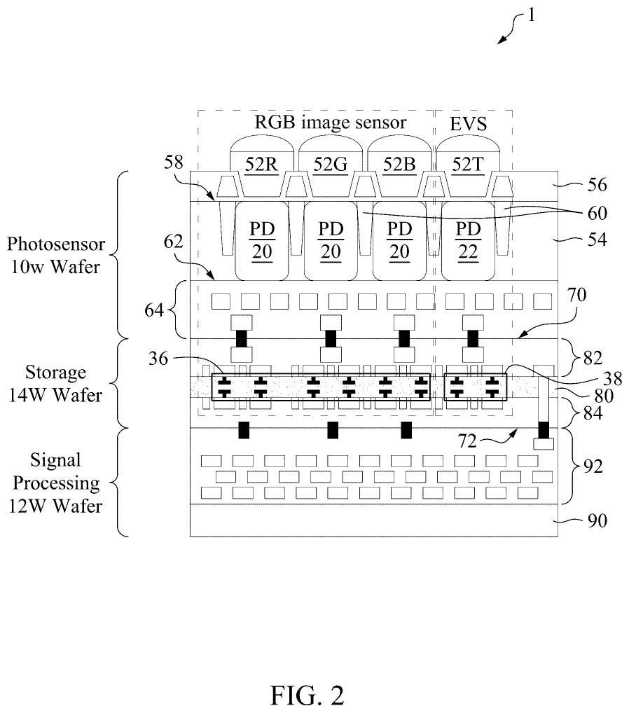

With reference to FIG. 2, in still yet another physical implementation each of the photosensor layer 10, storage layer 12, and signal processing layer 14 is fabricated on a separate wafer, and the three wafers are are bonded together with electrical interconnects between the wafers. FIG. 2 diagrammatically illustrates a side sectional view of an image sensor 1 with photosensors 16 and EVS photosensors 18 as described with reference to FIG. 1, in which the photosensor layer 10 is disposed on and/or in a photosensor wafer 10W, the storage layer 14 is disposed on and/or in a storage wafer 14W, and the signal processing layer 14 is disposed on and/or in a signal processing wafer 12W. It will be appreciated that while FIG. 2 is described in terms of a photosensor wafer 10W, a signal processing wafer 12W, and an interposed storage wafer 14W that are bonded together as shown in FIG. 2, these may alternatively be viewed as a photosensor die 10W, a signal processing die 12W, and an interposed storage die 14W that are bonded together as shown in FIG. 2 (where the photosensor die is diced from a photosensor wafer, the signal processing die is diced from a signal processing wafer, and the storage die is diced from a storage wafer). In a nonlimiting illustrative embodiment, the photosensor wafer 10W has a thickness of between 2 microns and 5 microns; the signal processing wafer 12W has a thickness of between 3 microns and 4 microns; and the storage wafer 14W has a thickness between 1 micron and 2 microns. However, these are merely nonlimiting illustrative examples.

The photosensor wafer 10W includes a two-dimensional array of photodiodes 20, 22, where (referencing back to FIG. 1) the photodiodes 20 are components of photosensors 16 and the photodiodes 22 are components of EVS photosensors 18. In the example of FIG. 2, the photosensors include: red photosensors 16 that are sensitive to red light due to placement of a red light-transmissive filter or lens 52R over the corresponding photodiode 20; green photosensors that are sensitive to green light due to placement of a green light-transmissive filter or lens 52G over the corresponding photodiode 20; and blue photosensors that are sensitive to blue light due to placement of a blue light-transmissive filter or lens 52B over the corresponding photodiode 20. The illustrative EVS photosensor of FIG. 2 includes a transparent light-transmissive window or lens 52T placed over the photodiode 22 of the EVS photosensor. This provides a monochromatic EVS sensor array. In a variant embodiment (not shown in FIG. 2), the EVS photosensors can variously include red, green, and blue filters to provide a color EVS sensor array.

The illustrative photosensor wafer 10W comprises a silicon substrate 54 in and/or on which the photodiodes 20 and 22 are fabricated, along with the corresponding electronics of the photosensor layer 10 of FIG. 1 (these not being shown in FIG. 2). The photodiodes 20 and 22 may be formed by suitable dopant diffusion or implantation (e.g., if the silicon substrate 54 is doped n-type then a p-type dopant diffusion or implantation can be performed in forming the photodiodes 20 and 22; or, conversely, if the silicon substrate 54 is doped p-type then an n-type dopant diffusion or implantation can be performed in forming the photodiodes 20 and 22). A silicon dioxide or other dielectric layer or layer stack 56 is disposed on a light-receiving surface 58 of the silicon substrate 54, and trench isolation regions 60 of silicon dioxide or another dielectric material (e.g., shallow trench isolation regions, or deep trench isolation regions) are interposed between the photodiodes to provide isolation therebetween. On an opposite side 62 of the silicon substrate 54, a metallization stack 64 is formed, e.g., by back end-of-line (BEOL) processing. The metallization stack 64 comprises a plurality of patterned metal (e.g., copper) layers spaced apart by intermetal dielectric (IMD) material with electrical vias passing through (details not shown), and provides electrical traces for electrically interconnecting the photodiodes 20 and 22 and other electronic components of the photosensor layer 10.

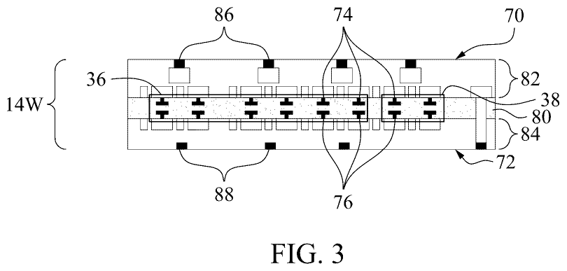

With continuing reference to FIG. 2 and with further reference to FIG. 3 which diagrammatically illustrates an isolation side sectional view of the storage wafer 14W of the image sensor 1 of FIG. 2, the storage wafer 14W is interposed between the photosensor wafer 10W and the signal processing wafer 12W. The storage wafer 14W includes the MIM storage elements 36 and 38. The storage wafer 14W has a first side 70 facing the photosensor wafer 10W, and an opposite second side 72 facing the signal processing wafer 12W. The MIM storage elements 36 and 38 have first terminals 74 and second terminals 76, labeled only in FIG. 3. The first terminals 74 are electrically connected with the photosensors 16 and 18, respectively, of the photosensor wafer 10W on the first side 70 of the storage wafer 14W which faces the photosensor wafer 10W, and the second terminals 76 are electrically connected with the signal processing circuitry of the signal processing wafer 12W on the second side 72 of the storage wafer 14W that faces the signal processing wafer 12W.

The illustrative storage wafer 14W includes a silicon substrate 80 on and/or in which the MIM storage elements 36 and 38 are fabricated. A first metallization stack 82 is formed on a first side of the silicon substrate 80, with the surface of the first metallization stack 82 distal from the substrate 80 being the first side 70 of the storage wafer 14W. A second metallization stack 84 is formed on an opposite second side of the silicon substrate 80, with the surface of the second metallization stack 84 distal from the substrate 80 being the second side 72 of the storage wafer 14W. The first metallization stack 82 provides electrical traces for connecting the first terminals 74 of the MIM storage elements 36 and 38 (see FIG. 3) with the photosensor wafer 10W. The second metallization stack 84 provides electrical traces for connecting the second terminals 76 of the MIM storage elements 36 and 38 (see FIG. 3) with the signal processing wafer 12W. As seen in FIG. 3, the first side 70 of the storage wafer 14W includes copper contacts 86 for connecting with mating contacts (see FIG. 2) of the photosensor wafer 10W; and likewise the second side 72 of the storage wafer 14W includes copper contacts 88 for connecting with mating contacts (see FIG. 2) of the signal processing wafer 12W. The contacts 86 and 88 may for example be copper contacts, and similarly for the mating contacts of the respective photosensor and signal processing wafers 10W and 12W.

The signal processing wafer 12W includes a silicon substrate 90 in and/or on which the signal processing circuitry of the signal processing layer 12 (see FIG. 1) is fabricated, and a metallization stack 92 for providing electrical traces for connecting the signal processing circuitry with the contacts 88 on the second side 72 of the storage wafer 14W. The signal processing circuitry may be fabricated on and/or in the silicon substrate 90 by CMOS fabrication processes, for example.

In the stack of three wafers 10W, 12W, 14W shown in FIG. 2, the photosensors 16, 18 of the photosensor wafer 10W are electrically connected to transfer photocharge collected by the photosensors 16, 18 to the MIM storage elements 36, 38 of the storage wafer 14W, and the MIM storage elements 36, 38 of the storage wafer 14W are connected to transfer the photocharge to the signal processing circuitry 12 of the signal processing wafer 12W. The MIM storage elements 36, 38 provide increased photocharge storage capacity for the photosensors 16, 18, thus improving image sensor performance characteristics such as the full well capacity (FWC) and dynamic range of the image sensor.

In the stack of three wafers 10W, 12W, 14W shown in FIG. 2, the photosensors 16, 18 of the photosensor wafer 10W are indirectly electrically connected with the signal processing circuitry 12 of the signal processing wafer 12W via the MIM storage elements 36, 38 of the storage wafer 14W, rather than being directly electrically connected with the signal processing circuitry 12 of the signal processing wafer 12W.

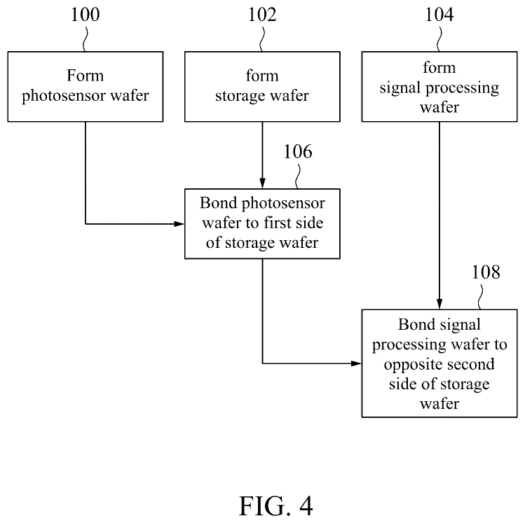

With reference to FIG. 4, fabrication of the image sensor 1 of FIG. 2 is described. In an operation 100, the photosensor wafer 10W is formed. In an operation 102, the storage wafer 14W is formed. In an operation 104, the signal processing wafer 12W is formed. The operations 100, 102, and 104 suitably employ silicon fabrication techniques for front end-of-line (FEOL) processing to form the electronic devices (e.g., photodiodes 20 and 22 and circuit components such as the illustrative transistors RST, SF, TG, RSL shown in FIG. 1, and the MIM storage elements 36 and 38; followed by BEOL processing to form the various metallization stacks 64, 82, 84, 92. The order of the operations 100, 102, and 104 can vary, and/or these operations may be performed concurrently using different tools of a semiconductor fabrication facility.

In an operation 106 the photosensor wafer 10W is bonded to the first side 70 of the storage wafer 14W. The operation 106 electrically connects the photosensors 16, 18 of the photosensor wafer 10W and MIM storage elements 36, 38 of the storage wafer 14W, e.g. via the copper contacts 86 of the storage wafer 14W. In an operation 108 the signal processing wafer 12W is bonded to the second side 72 of the storage wafer 14W. The operation 106 electrically connects the MIM storage elements 36, 38 of the storage wafer 14W with the signal processing circuitry 12 of the signal processing wafer 12W, e.g. via the copper contacts 88 of the storage wafer 14W. The order of the operations 106 and 108 may be reversed, or the operations may be done simultaneously (e.g., stacking the three wafers 10W, 14W, and 12W and applying energy in the form of heat, pressure, acoustic energy, and/or so forth to form bonds with the copper contacts 86 and 88).

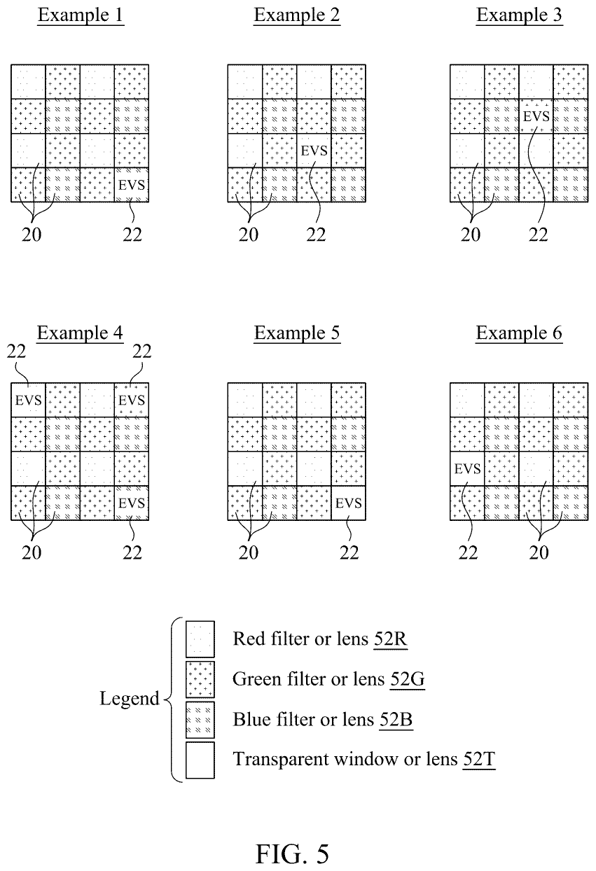

With reference now to FIG. 5, the imaging sensor can have various photosensor layouts providing combined color and EVS imaging. FIG. 5 shows five nonlimiting illustrative examples of such layouts. The diagrammatic representations of FIG. 5 indicate the color photodiodes 20 as unlabeled square boxes, and the EVS photodiodes 22 as square boxes labeled “EVS”. As indicated in the legend of FIG. 5, different hatchings of the square boxes are used to distinguish pixels with red filters or lenses 52R, green filters or lenses 52G, blue filters or lenses 52B, and transparent windows or lenses 52T. In each of the examples of FIG. 5, the array of color photosensors 20 employs 2×2 photosensor units each two green photosensors, one red photosensor, and one blue photosensor, to approximate the color spectral sensitivity of the human eye which has highest sensitivity for green light and lower sensitivity for red and blue light. Each example in FIG. 5 shows a 4×4 array of 16 photosensors (or, equivalently, a 2×2 array of 2×2 photosensor units). It will be appreciated that the depicted 4×4 array can be considered as a portion of a larger array with a desired total number of pixels.

In FIG. 5, Example 1, the 4×4 array (portion) of photosensors 20, 22 includes fifteen photosensors 20 providing the color imaging, and one EVS photosensor 22 for EVS imaging. The illustrative EVS photosensor 22 of Example 1 replaces one blue pixel of the color imaging array, and has a blue filter or lens 52B which would provide EVS imaging sensitive to blue light.

In FIG. 5, Example 2, the 4×4 array (portion) of photosensors 20, 22 includes fifteen photosensors 20 providing the color imaging, and one EVS photosensor 22 for EVS imaging. The illustrative EVS photosensor 22 of Example 2 replaces one red pixel of the color imaging array, and has a red filter or lens 52R which would provide EVS imaging sensitive to red light.

In FIG. 5, Example 3, the 4×4 array (portion) of photosensors 20, 22 includes fifteen photosensors 20 providing the color imaging, and one EVS photosensor 22 for EVS imaging. The illustrative EVS photosensor 22 of Example 3 replaces one green pixel of the color imaging array, and has a green filter or lens 52G which would provide EVS imaging sensitive to green light.

In FIG. 5, Example 4, the 4×4 array (portion) of photosensors 20, 22 includes thirteen photosensors 20 providing the color imaging, and three EVS photosensors 22 for EVS imaging. The illustrative three EVS photosensors 22 of Example 4 replace one blue pixel, one red pixel, and one green pixel, respectively, of the color imaging array, and the three EVS photosensors 22 have a red filter or lens 52R, a green filter or lens 52G, and a blue filter or lens 52B, respectively. With suitable circuitry in the signal processing layer 12 (see FIG. 1), the array of Example 4 can provide color EVS imaging.

In FIG. 5, Example 5, the 4×4 array (portion) of photosensors 20, 22 includes fifteen photosensors 20 providing the color imaging, and one EVS photosensor 22 for EVS imaging. As in Example 1, the illustrative EVS photosensor 22 of Example 5 replaces one blue pixel of the color imaging array. However, in Example 5 the EVS photosensor 22 has a transparent window or lens 52T which would provide monochromatic EVS imaging that is sensitive across the visible spectrum.

In FIG. 5, Example 6, the 4×4 array (portion) of photosensors 20, 22 includes fifteen photosensors 20 providing the color imaging, and one EVS photosensor 22 for EVS imaging. The illustrative EVS photosensor 22 of Example 6 replaces one red pixel of the color imaging array. As with Example 5, in Example 6 the EVS photosensor 22 has a transparent window or lens 52T which would provide monochromatic EVS imaging that is sensitive across the visible spectrum.

It will be appreciated that Examples 1-6 of FIG. 5 are nonlimiting examples, and that other layouts combining color imaging and monochromatic, single-color, or full-color EVS imaging are contemplated. As a further example, an array with 16×16 pixels could be constructed by alternating 4×4 pixel sub-arrays with arrangements of Example 1, Example 2, and Example 3, to provide full-color EVS imaging with a higher ratio of color pixels to EVS pixels than is the case in Example 4. In a further variant of such an assembly, there may be twice as many 4×4 sub-arrays of the type shown in Example 3 (i.e., with green EVS sensors) versus the sub-arrays of the type shown Example 1 (i.e., with blue EVS sensors) or Example 2 (i.e., with red EVS sensors), to provide a full-color EVS image sensor with higher sensitivity to green light to mimic human vision.

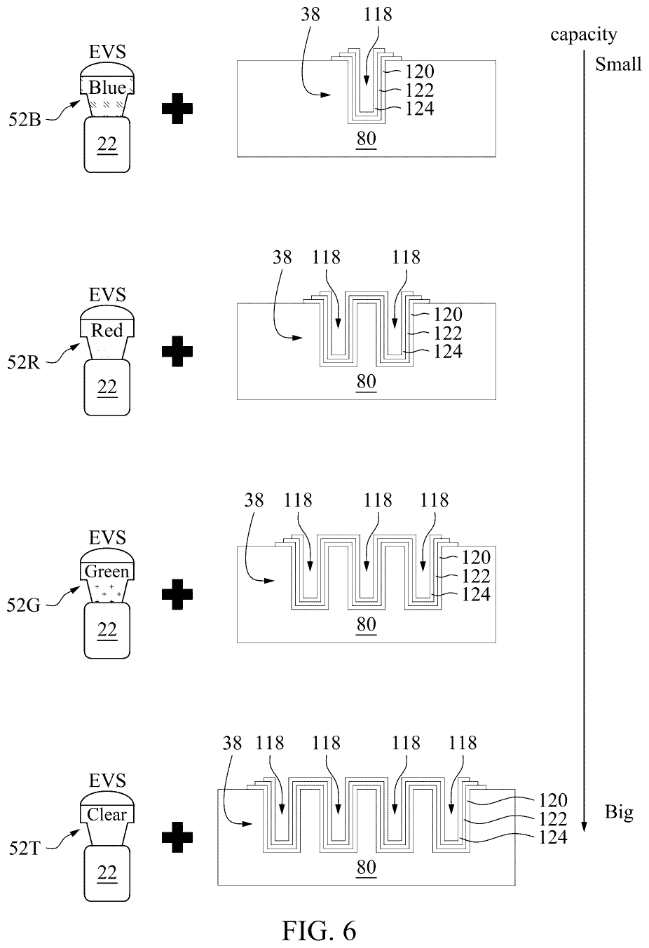

With reference now to FIG. 6, some illustrative embodiments of the MIM storage elements 38 are shown. With reference back to FIG. 1, the MIM storage elements are connected in series with the EVS photosensors 16. As previously mentioned with reference to FIGS. 2 and 3, the MIM storage elements 36 and 38 are suitably fabricated in or on a silicon wafer 80 of the storage wafer 14W. In the nonlimiting illustrative examples of FIG. 6, each MIM storage element 38 is formed as a three-dimensional MIM (3D-MIM) storage element. To this end, at least one cavity 118 is formed in the silicon wafer 80. A first (e.g., lower) conductive layer 120 is conformally disposed on the inside surface of the at least one cavity 118 and on the surface of the silicon wafer 80 extending between the cavities 118 (if there are two or more cavities 118). A dielectric layer 122 is then conformally disposed on the first (e.g., lower) conductive layer 120. A second (e.g., upper) conductive layer 124 is conformally disposed on the dielectric layer 122. The three layers 120, 122, 124 thus form the MIM storage element. Although not shown in FIG. 6, after disposition of the second (e.g., upper) conductive layer 124 a dielectric material may be disposed on the surface of the silicon wafer 80 at a depth sufficient to fill the remaining space inside the at least one cavity 118, followed by planarization of the upper surface of the dielectric material using chemical mechanical polishing (CMP) or the like. Also, although not shown in FIG. 6, one of the conductive layers, e.g., the first or lower conductive layer 120, is suitably electrically connected with the second terminals 76 shown in FIG. 3, while the other of the conductive layers, e.g., the second or upper conductive layer 124, is suitably electrically connected with the first terminals 74 shown in FIG. 3.

In general, the photocharge storage capacity of the MIM storage element scales with its area. The area of the 3D-MIM storage elements 38 of FIG. 6 is increased due to the additional area provided by the cavity or cavities 118. Thus, using 3D-MIM structures as the MIM storage elements 38, as shown in FIG. 6, advantageously increases the photocharge storage capacity for a given device area.

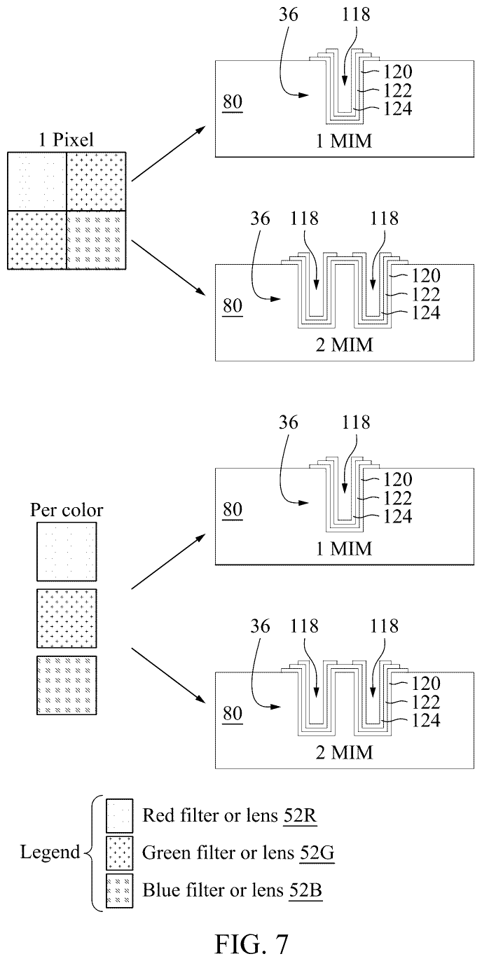

FIG. 6 depicts 3D-MIM storage elements 38 suitably used to increase the photocharge storage capacity of the EVS photosensors 18 (see FIG. 1). It will be appreciated that the same 3D-MIM structure can also be used for the MIM storage elements 36 that are used to increase the photocharge storage capacity of the photosensors 16 of the color image sensor. This is shown in FIG. 7, which is further discussed later herein.

With continuing reference to FIG. 6, the EVS storage elements 38 may benefit from having different photocharge storage capacities depending on the characteristics of the connected EVS photosensor 18. In the examples of FIG. 18, for an EVS photosensor 22 optically coupled with an illustrated blue filter or lens 52B, a small photocharge storage capacity may be sufficient, as achieved in FIG. 6 using a 3D-MIM storage element 38 with only a single cavity 118. For an EVS photosensor 22 optically coupled with an illustrated red filter or lens 52R, a larger photocharge storage capacity may be sufficient, as achieved in FIG. 6 using a 3D-MIM storage element 38 with two cavities 118. For an EVS photosensor 22 optically coupled with an illustrated green filter or lens 52G, a still larger photocharge storage capacity may be sufficient, as achieved in FIG. 6 using a 3D-MIM storage element 38 with three cavities 118. These difference in photocharge storage capacity between the blue, red, and green EVS pixels approximately maps to the spectral sensitivity of the human eye, which is most sensitive to green light and least sensitive to blue light. FIG. 6 also shows a fourth example, in which an EVS photosensor 22 is optically coupled with an illustrated transparent window or lens 52T. Here, the largest photocharge storage capacity may be desirable, as achieved in FIG. 6 using a 3D-MIM storage element 38 with four cavities 118. This may be desirable since the transparent window or lens 52T passes all of red, green, and blue light so that it will typically collect the highest amount of photocharge in a given EVS imaging situation. In general, using an MIM storage element with the smallest photocharge storage capacity suitable for that photosensor is beneficial since a smaller MIM storage element can be used.

With reference to FIG. 7, in the case of the color photosensors 16 it is diagrammatically illustrated that two or more photosensors 16 may be connected with a given MIM storage element 36, and the size of the MIM storage elements 36 (e.g., controlled by the number of cavities 118) may be chosen based on the expected amount of charge storage capacity needed. For example, FIG. 7 shows a single full-color pixel including one red photosensor (i.e., one photodiode 16 optically coupled with a red filter or lens 52R), one blue photosensor (i.e., one photodiode 16 optically coupled with a blue filter or lens 52B), and two green photosensors (i.e., two photodiodes 16 each optically coupled with a green filter or lens 52G). As previously noted, having two green (sub-) pixels in the full-color pixel provides closer matching to the human eye spectral sensitivity which peaks in the green. In this configuration, each of the red and blue pixels may be connected with a smaller 3D-MIM storage element 36 with a single cavity 36, while the two green pixels may both be connected to a single larger 3D-MIM storage element 36 with two cavities 118 (thereby providing higher photocharge storage capacity to accommodate the photocharge accumulated by the two green pixels).

The lower portion of FIG. 7 diagrammatically shows an example in which each photosensor is connected with a single corresponding 3D-MIM storage element 36. As with the EVS photosensor examples of FIG. 6, the photocharge storage capacity may vary depending on the color of the pixel, e.g. 3D-MIM storage element 36 with a single cavity 118 may be used for a red or blue pixel, while a 3D-MIM storage element 36 with two cavities 118 may be used for a green pixel.

It will be appreciated that FIG. 7 shows some nonlimiting illustrative examples, and other connection arrangements are also contemplated.

In the examples of FIGS. 6 and 7, the 3D-MIM storage elements 36 and 38 employ square wells or cavities 118. However, other types of MIM storage elements may be employed.

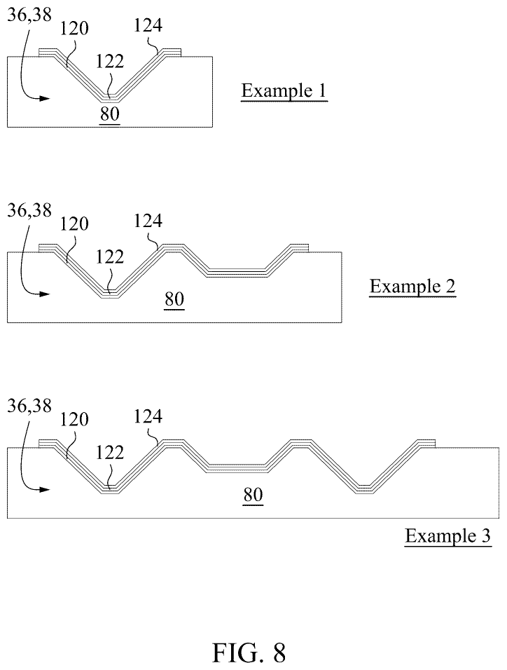

With reference to FIG. 8, some further examples of suitable MIM storage elements 36, 38 are shown. In FIG. 8, Example 1, a 3D-MIM storage element is formed with a single well or cavity having a first shape. In FIG. 8, Example 2, a 3D-MIM storage element is formed with two wells or cavities, one having the first shape and the other having a second shape that is different than the first shape. In FIG. 8, Example 3, a 3D-MIM storage element is formed with three wells or cavities, two having the first shape and the third having the second shape.

An advantage of the approach of FIG. 8 is the photocharge storage capacity can be more finely tuned. For example, if a well or cavity having the first shape has a first photocharge storage capacity Q₁ and a well or cavity having the second shape has a different photocharge storage capacity Q₂, then the total photocharge storage capacity of a given MIM storage element can be computed as A×Q₁+B×Q₂ where A is the number of wells or cavities of the MIM storage element having the first shape and B is the number of wells or cavities of the MIM storage element having the second shape.

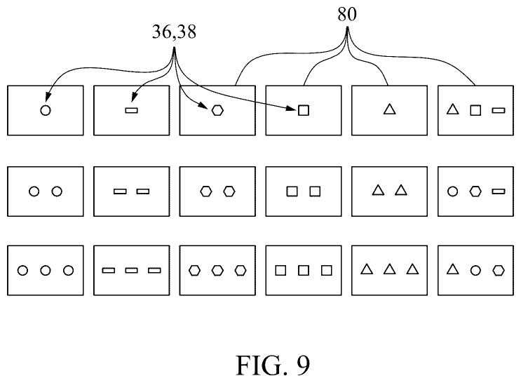

With reference to FIG. 9, it is shown that the MIM storage elements 36 or 38 can have different layouts, as seen in the diagrammatic top views of FIG. 9 showing MIM storage elements 36, 38 having circular, rectangular, hexagonal, square, or triangular perimeters. These are merely nonlimiting illustrative examples. Moreover, as diagrammatically shown in FIG. 9, different MIM storage elements in the same imaging sensor can have different layouts or perimeters.

The total photocharge storage capacity is a combination of the photocharge storage capacity of the photosensor 16 or 18 and its series-connected MIM storage element 36 or 38. In general, the photocharge storage capacity of the MIM storage element 36 or 38 is greater than the photocharge storage capacity of the connected photosensor 16 or 18. In such embodiments, each photosensor 16 has an photocharge storage capacity that is less than an photocharge storage capacity of the MIM storage element 36 with which it is electrically connected; and, each EVS photosensor 18 has an photocharge storage capacity that is less than an photocharge storage capacity of the MIM storage element 38 with which it is electrically connected.

In the following, some further embodiments are described.

In a nonlimiting illustrative embodiment, a method is disclosed of fabricating an image sensor. The method includes: forming a photosensor wafer comprising an array of photosensors; forming a signal processing wafer comprising signal processing circuitry configured to receive and process photocharge collected by the photosensors of the photosensor wafer; forming a storage wafer comprising metal-insulator-metal (MIM) storage elements; securing the photosensor wafer to a first side of the storage wafer wherein the securing electrically connects the photosensors of the photosensor wafer and MIM storage elements of the storage wafer; and securing the signal processing wafer to a second side of the storage wafer wherein the securing electrically connects the MIM storage elements of the storage wafer with the signal processing circuitry of the signal processing wafer.

In a nonlimiting illustrative embodiment, an image sensor includes a photosensor wafer comprising an array of photosensors, a signal processing wafer comprising signal processing circuitry configured to receive and process photocharge collected by the photosensors of the photosensor wafer, and a storage wafer interposed between the photosensor wafer and the signal processing wafer and comprising MIM storage elements having first terminals electrically connected with the photosensors of the photosensor wafer and second terminals electrically connected with the signal processing circuitry of the signal processing wafer.

In a nonlimiting illustrative embodiment, an image sensor includes a photosensor layer comprising an array of photosensors, a signal processing layer comprising signal processing circuitry configured to receive and process photocharge collected by the photosensors of the photosensor layer, and a storage layer comprising MIM storage elements electrically connected in series between the photosensors of the photosensor layer and the signal processing circuitry of the signal processing layer.

In a method of fabricating an image sensor, a photosensor wafer is formed, comprising an array of photosensors. A signal processing wafer is formed, comprising signal processing circuitry configured to receive and process photocharge collected by the photosensors of the photosensor wafer. A storage wafer is formed, comprising metal-insulator-metal (MIM) storage elements. The photosensor wafer is secured to a first side of the storage wafer, thereby electrically connecting the photosensors of the photosensor wafer and MIM storage elements of the storage wafer. The signal processing wafer is secured to a second side of the storage wafer, thereby electrically connecting the MIM storage elements of the storage wafer with the signal processing circuitry of the signal processing wafer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating an image sensor, the method comprising:
forming a photosensor wafer comprising an array of photosensors;
forming a signal processing wafer comprising signal processing circuitry configured to receive and process photocharge collected by the photosensors of the photosensor wafer;
forming a storage wafer comprising metal-insulator-metal (MIM) storage elements;
securing the photosensor wafer to a first side of the storage wafer wherein the securing electrically connects the photosensors of the photosensor wafer and MIM storage elements of the storage wafer; and
securing the signal processing wafer to a second side of the storage wafer wherein the securing electrically connects the MIM storage elements of the storage wafer with the signal processing circuitry of the signal processing wafer.

2. The method of claim 1, wherein after securing the photosensor wafer to the first side of the storage wafer and securing the signal processing wafer to the second side of the storage wafer, each photosensor is electrically connected in series with a MIM storage element of the storage wafer.

3. The method of claim 1, wherein:
the photosensors include event vision sensor (EVS) photosensors, and
after securing the photosensor wafer to the first side of the storage wafer, each EVS photosensor of the photosensor wafer is electrically connected with a MIM storage element of the storage wafer.

4. The method of claim 3, wherein each EVS photosensor has a photocharge storage capacity that is less than a photocharge storage capacity of the MIM storage element with which it is electrically connected.

5. The method of claim 1, wherein:
the photosensors include red photosensors having red color filters, green photosensors having green color filters, and blue photosensors having blue color filters, and
after securing the photosensor wafer to the first side of the storage wafer, each red photosensor of the photosensor wafer is electrically connected with a MIM storage element of the storage wafer, and each green photosensor of the photosensor wafer is electrically connected with a MIM storage element of the storage wafer, and each blue photosensor of the photosensor wafer is electrically connected with a MIM storage element of the storage wafer.

6. The method of claim 5, wherein:
each red photosensor has a photocharge storage capacity that is less than a photocharge storage capacity of the MIM storage element with which it is electrically connected;
each green photosensor has a photocharge storage capacity that is less than a photocharge storage capacity of the MIM storage element with which it is electrically connected; and
each blue photosensor has a photocharge storage capacity that is less than a photocharge storage capacity of the MIM storage element with which it is electrically connected.

7. The method of claim 5, wherein:
each blue photosensor is electrically connected with a MIM storage element having a first photocharge storage capacity;
each red photosensor is electrically connected with a MIM storage element having a second photocharge storage capacity that is larger than the first photocharge storage capacity;
each green photosensor is electrically connected with a MIM storage element having a third photocharge storage capacity that is larger than the second photocharge storage capacity.

8. The method of claim 7, wherein:
the photosensors further include event vision sensor (EVS) photosensors, and
after securing the photosensor wafer to the first side of the storage wafer, each EVS photosensor of the photosensor wafer is electrically connected with a MIM storage element of the storage wafer having a fourth charge storage capacity that is larger than the third photocharge storage capacity.

9. An image sensor comprising:
a photosensor wafer comprising an array of photosensors;
a signal processing wafer comprising signal processing circuitry configured to receive and process photocharge collected by the photosensors of the photosensor wafer; and
a storage wafer interposed between the photosensor wafer and the signal processing wafer and comprising metal-insulator-metal (MIM) storage elements having first terminals electrically connected with the photosensors of the photosensor wafer and second terminals electrically connected with the signal processing circuitry of the signal processing wafer.

10. The image sensor of claim 9, wherein the photosensors of the photosensor wafer are electrically connected to transfer photocharge collected by the photosensors to the MIM storage elements of the storage wafer, and the MIM storage elements of the storage wafer are connected to transfer the photocharge to the signal processing circuitry of the signal processing wafer.

11. The image sensor of claim 9, wherein:
the photosensors of the photosensor wafer are indirectly electrically connected with the signal processing circuitry of the signal processing wafer via the MIM storage elements of the storage wafer, and
the photosensors of the photosensor wafer are not directly electrically connected with the signal processing circuitry of the signal processing wafer.

12. The image sensor of claim 9, wherein:
the photosensors include event vision sensor (EVS) photosensors, and each EVS photosensor has a photocharge storage capacity that is less than a photocharge storage capacity of a MIM storage element with which it is electrically connected.

13. The image sensor of claim 9, wherein:
the photosensors include red photosensors having red color filters, green photosensors having green color filters, and blue photosensors having blue color filters,
each red photosensor of the photosensor wafer is electrically connected with a MIM storage element of the storage wafer,
each green photosensor of the photosensor wafer is electrically connected with a MIM storage element of the storage wafer, and
each blue photosensor of the photosensor wafer is electrically connected with a MIM storage element of the storage wafer.

14. The image sensor of claim 13, wherein:
each red photosensor has a photocharge storage capacity that is less than a photocharge storage capacity of the MIM storage element with which it is electrically connected;
each green photosensor has a photocharge storage capacity that is less than a photocharge storage capacity of the MIM storage element with which it is electrically connected; and
each blue photosensor has a photocharge storage capacity that is less than a photocharge storage capacity of the MIM storage element with which it is electrically connected.

15. The image sensor of claim 13, wherein:
each blue photosensor is electrically connected with a MIM storage element having a first photocharge storage capacity;
each red photosensor is electrically connected with a MIM storage element having a second photocharge storage capacity that is larger than the first photocharge storage capacity;
each green photosensor is electrically connected with a MIM storage element having a third photocharge storage capacity that is larger than the second photocharge storage capacity.

16. The image sensor of claim 15, wherein:
the photosensors further include event vision sensor (EVS) photosensors, and
each EVS photosensor of the photosensor wafer is electrically connected with a MIM storage element of the storage wafer having a fourth charge storage capacity that is larger than the third photocharge storage capacity.

17. An image sensor comprising:
a photosensor layer comprising an array of photosensors;
a signal processing layer comprising signal processing circuitry configured to receive and process photocharge collected by the photosensors of the photosensor layer; and
a storage layer comprising metal-insulator-metal (MIM) storage elements electrically connected in series between the photosensors of the photosensor layer and the signal processing circuitry of the signal processing layer.

18. The image sensor of claim 17 wherein:
the photosensor layer is disposed on and/or in a photosensor wafer;
the storage layer is disposed on and/or in a storage wafer;
the signal processing layer is disposed on and/or in a signal processing wafer; and
the photosensor wafer is secured to a first side of the storage wafer and the signal processing wafer is secured to an opposite second side of the storage wafer.

19. The image sensor of claim 17, wherein:
the photosensors include event vision sensor (EVS) photosensors, and each EVS photosensor has a photocharge storage capacity that is less than a photocharge storage capacity of a MIM storage element with which it is electrically connected.

20. The image sensor of claim 19, wherein:
the photosensors further include red photosensors having red color filters, green photosensors having green color filters, and blue photosensors having blue color filters,
each red photosensor of the photosensor wafer is electrically connected with a MIM storage element of the storage wafer,
each green photosensor of the photosensor wafer is electrically connected with a MIM storage element of the storage wafer, and
each blue photosensor of the photosensor wafer is electrically connected with a MIM storage element of the storage wafer.
